(19) United States
(12) Patent Application Publication
(10) Pub. No.: US 2013/0194137 A1
(43) Pub. Date: Aug. 1, 2013

(54) MOBILE WIRELESS COMMUNICATIONS DEVICE INCLUDING RIGID MECHANICAL STIFFENER SLOT ANTENNA AND RELATED METHODS

(71) Applicant: Seong Heon JEONG, Irving, TX (US)

(72) Inventor: Seong Heon JEONG, Irving, TX (US)

(73) Assignee: RESEARCH IN MOTION LIMITED, WATERLOO (CA)

(21) Appl. No.: 13/360,139

(22) Filed: Jan. 27, 2012

(51) Int. Cl. H01Q 1/24; H01P 11/00; H05K 3/32

(52) U.S. Cl. 343/702; 29/832; 29/601

(57) ABSTRACT

A mobile wireless communications device may include a portable housing and a printed circuit board carried by the portable housing. The mobile wireless communications device may also include a rigid mechanical stiffener carried by the portable housing and may include an electrically conductive material. The rigid mechanical stiffener may have a slot therein adjacent an end thereof to define a slot antenna. Wireless transceiver circuitry may be carried by the PCB and coupled to the slot antenna. In some embodiments, the slot antenna may be cooperate with another antenna carried by the portable housing.

### TECHNICAL FIELD

The present disclosure generally relates to the field of wireless communications systems, and, more particularly, to mobile wireless communications devices and related methods.

### BACKGROUND

Mobile wireless communications systems continue to grow in popularity and have become an integral part of both personal and business communications. For example, cellular telephones allow users to place and receive voice calls almost anywhere they travel, while tablet personal computers allow mobile data communications almost anywhere. Moreover, as mobile communications technology, for example, cellular communications technology, has increased, so too has the functionality of cellular devices and the different types of devices available to users. For example, many cellular devices now incorporate personal digital assistant (PDA) features such as calendars, address books, task lists, etc. Moreover, such multi-function devices, including, for example, tablet personal computers, may also allow users to wirelessly send and receive electronic mail (email) messages and access the Internet via a cellular network and/or a wireless local area network (WLAN), for example.

Even so, as the functionality of cellular communications devices continues to increase, so too does the demand for smaller devices which are easier and more convenient for users to carry. One challenge this poses for cellular device manufacturers is designing antennas that provide desired operating characteristics and desired mechanical strength within the relatively limited amount of space available for antennas and within operating guidelines for a given device.

### BRIEF DESCRIPTION OF THE DRAWINGS

FIG. 1 is an exploded view of a mobile wireless communications device including a rigid mechanical stiffener in accordance with one example embodiment.

FIG. 2 is a top schematic diagram of the rigid mechanical stiffener of FIG. 1.

FIG. 3 is a schematic diagram of a conventional slot antenna in accordance with the prior art.

FIG. 4 is a measured reflection coefficient graph for the rigid mechanical stiffener of the device in FIG. 1.

FIG. 5 is a perspective view of the rigid mechanical stiffener of FIG. 1 including a dielectric body within the slot.

FIG. 6 is an enlarged top perspective view of the rigid mechanical stiffener and the further antenna of the device of FIG. 1.

FIG. 7 is a bottom perspective view of the rigid mechanical stiffener and further antenna of the device of FIG. 1.

FIG. 8 is a measured reflection coefficient graph for the rigid mechanical stiffener and the further antenna of the device of FIG. 1.

FIG. 9 is a schematic block diagram illustrating additional components that may be included in the mobile wireless communications device of FIG. 1.

### DETAILED DESCRIPTION

The present description is made with reference to the accompanying drawings, in which various embodiments are shown. However, many different embodiments may be used, and thus the description should not be construed as limited to the embodiments set forth herein. Rather, these embodiments are provided so that this disclosure will be thorough and complete. Like numbers refer to like elements throughout.

In accordance with one exemplary aspect, a mobile wireless communications device may include a portable housing and a printed circuit board carried by the portable housing. The mobile wireless communications device may also include a rigid mechanical stiffener carried by the portable housing and may include an electrically conductive material. The rigid mechanical stiffener may have a slot therein adjacent an end thereof to define a slot antenna. Wireless transceiver circuitry may be carried by the PCB and coupled to the slot antenna.

The rigid mechanical stiffener may include a ring coupled to an inner periphery of the portable housing, and a plate extending across the ring. The plate may extend across a width of the portable housing, for example.

A dielectric body may be within the slot, for example. The rigid mechanical stiffener may include metal, for example.

The mobile wireless communications device may further include a further antenna carried by the portable housing and coupled to the wireless transceiver circuitry. The further antenna may include at least one planar inverted F-antenna (PIFA), for example. The further antenna may also be a flexible antenna, for example and may be carried between the portable housing and the rigid mechanical stiffener.

The mobile wireless communications device may further include a display carried by the mechanical stiffener. The portable housing may include a rear housing portion receiving the rigid mechanical stiffener therein, for example.

A method aspect is directed to a method of making a mobile wireless communications device that may include a portable housing, a printed circuit board (PCB) carried the portable housing, and wireless transceiver circuitry carried by the PCB. The method may include positioning a rigid mechanical stiffener to be carried by a portable housing and comprising an electrically conductive material. The rigid mechanical stiffener may have a slot therein adjacent an end thereof to define a slot antenna. The method may further include coupling the wireless transceiver circuitry to the slot antenna.

The method may include forming a rigid mechanical stiffener to be carried by a portable housing and including an electrically conductive material. The rigid mechanical stiffener 50 may have a slot therein adjacent an end thereof to define a slot antenna. The method may further include coupling wireless transceiver circuitry to the slot antenna, for example.

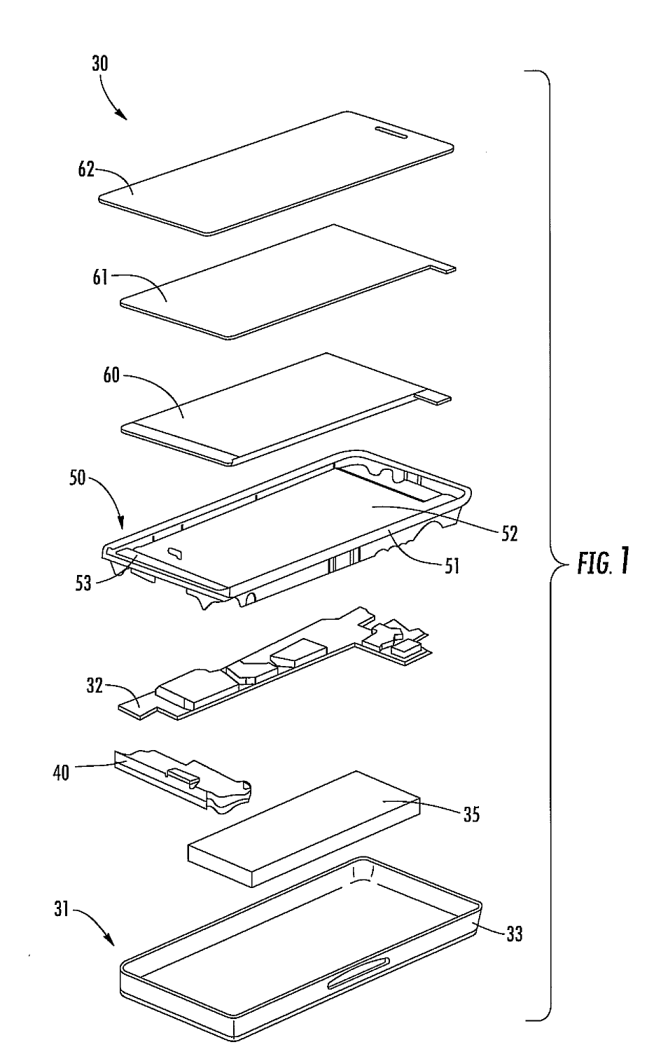

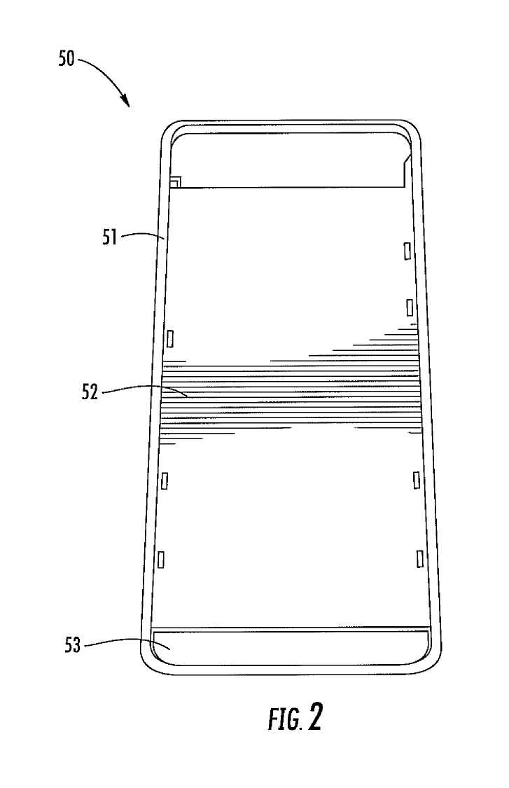

Referring initially to FIGS. 1-2, a mobile wireless communications device 30 illustratively includes a portable housing 31 having a rear portion 33, and a printed circuit board (PCB) 32, carried by the portable housing. A rigid mechanical stiffener 50 is carried by the rear portion 33 of the portable housing 31 and includes electrically conductive material. For example, the rigid mechanical stiffener 50 may be metal.

The rigid mechanical stiffener 50 includes a ring 51 coupled to an inner periphery of the rear portion 33 of the portable housing 31. A plate 52 extends across the ring 51 across the width of the portable housing 31. The rigid mechanical stiffener 50, and more particularly, the plate 52, has slot 53 adjacent an end thereof defining a slot antenna. It should be understood that an end may be a top, bottom, or side of the rigid mechanical stiffener 50 relative to the mobile device 30.

The rigid mechanical stiffener 50 may also include one or more fastener receiving passageways therein for receiving a respective mechanical fastener, for example, for securing the various components, as will be described herein. Moreover, the rigid mechanical stiffener 50 may also include surface contours to facilitate carrying some of components described herein.

A battery 35 is illustratively carried by the rigid mechanical stiffener 50. A further antenna 40 in the form of an antenna assembly is carried by the rear portion 33 of the portable housing 31 adjacent an end thereof. The further antenna 40 is coupled to wireless transceiver circuitry 34 carried by the PCB 32. Additional details of the further antenna 40 will be described in greater detail below.

The rigid mechanical stiffener 50 is carried by the rear portion 33 of the portable housing 31 so that it covers the further antenna 40, the battery 35, and the PCB 32. In other words, the further antenna 40, the battery 35, and the PCB 32 are carried between the portable housing 31 and the rigid mechanical stiffener 50.

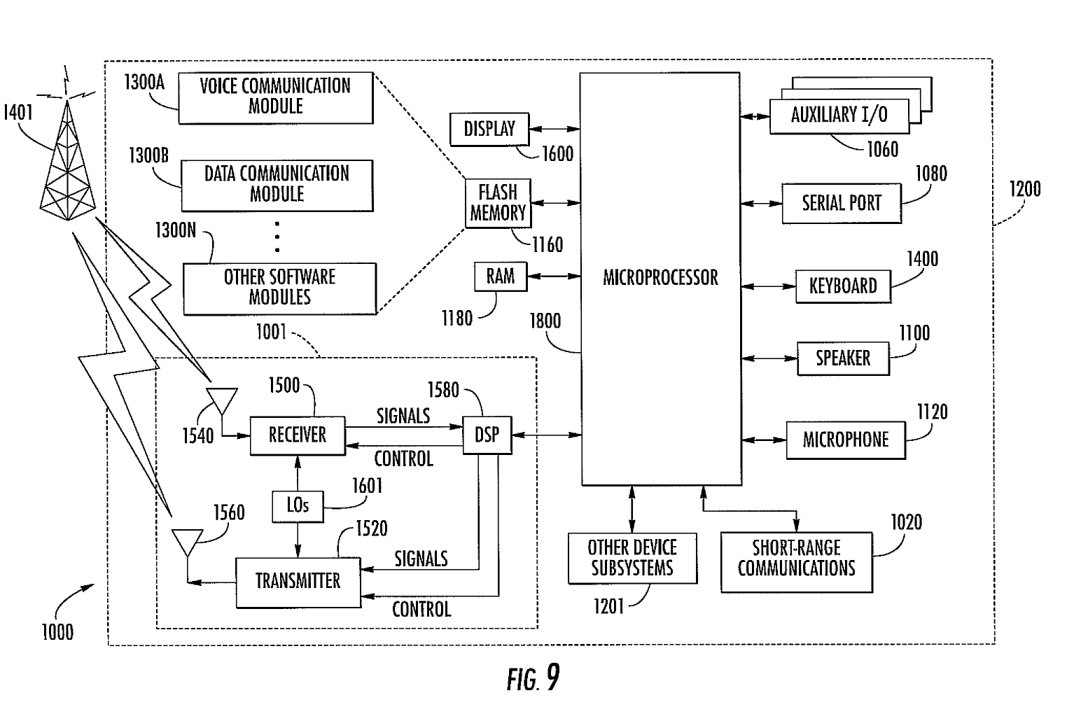

The exemplary device 30 further includes a display 60 carried by or within the ring 51 of the rigid mechanical stiffener 50. The display 60 may be a liquid crystal display (LCD) panel, for example. Of course, the display 60 may be another type of display. An input device 61 in the form of a touch panel is carried by rigid mechanical stiffener 50 over the display 60 and also within the ring 51, for example, as for use with a touch screen display. Of course, other and/or additional input devices may be used, for example, control keys. A cover 62, for example, a glass cover, is carried by the rigid mechanical stiffener 50 on top of the touch panel and within the ring 51. In other words, the display 60, the touch panel 61, and the cover 62 are in a stacked relation carried by the rigid mechanical stiffener 50 within the ring 51. The cover 62 may form the front portion of the portable housing 31. Operation of the various device components of an exemplary mobile wireless communications device will be described further below with reference to FIG. 9.

As will be appreciated by those skilled in the art, there has been increasing demand for a thinner mobile wireless communications device that includes a relatively large display, for example. Thus, with the increased size of the display, it may be desirable for mobile wireless communications device manufacturers to develop a mobile wireless communications device that has increased mechanically functionality and increased electrically functionality. Thus, to support this increased functionality it may be desirable to provide mechanical stability in a mobile wireless communications device.

One approach may be to include a relatively large, compared to the size of the portable housing, and relatively strong metallic object to provide increased mechanical strength across the entirety of the mobile wireless communications device. The metallic object may reduce the failure of the mobile wireless communications device from bending or dropping, for example.

The rigid mechanical stiffener 50 advantageously provides increased protection for the electronic components carried by the portable housing 31, for example, the components described above. In addition, the rigid mechanical stiffener 50 provides increased strength against outside force, for example dropping.

However, as will be appreciated by those skilled in the art, including a relatively large and relatively strong metallic object or stiffener within a portable housing may cause degradation of antenna performance due to the close proximity to an antenna trace. Thus, a metallic stiffener may negatively impact antenna performance and, thus, it is desirable that antenna design be such to reduce the effect thereof.

With the presence of a metallic stiffener, an ordinary antenna approach using a monopole, slot, loop, or planar inverted F-antenna (PIFA) may not provide relatively good radiation because the metallic stiffener causes a parasitic capacitance due to the close distance compared to the operating wavelength. In addition, a metallic stiffener also cancels the radiated wave by generating an out-of-phase reflected wave. Moreover, when the ground plane of the metallic stiffener may be close to the antenna feed, the bandwidth also becomes narrower, resulting in a poor efficiency across the band of interest. To address these problems, the rigid mechanical stiffener 50 of the present embodiments defines a radiator, or slot antenna, as noted above.

As background, a slot antenna is designed on an infinite ground by creating an aperture. A slot antenna typically has a uniform current distribution around the slot and is analyzed to be equivalent to a dipole antenna with introduction of a magnetic dipole. In a handheld application, for example, with a mobile wireless communications device, a slot antenna may often be designed with plus and minus terminals with a narrow gap in parallel, resulting in a relatively narrow bandwidth.

In contrast, the slot 53 in the plate 52 of the rigid mechanical stiffener 50 adjacent an end defines an asymmetric-ground slot antenna by using a mechanical geometry of the relatively large rigid mechanical stiffener 50. As will be appreciated by those skilled in the art, the slot 53 may be formed elsewhere in the rigid mechanical stiffener 50 as any slot may define a slot antenna.

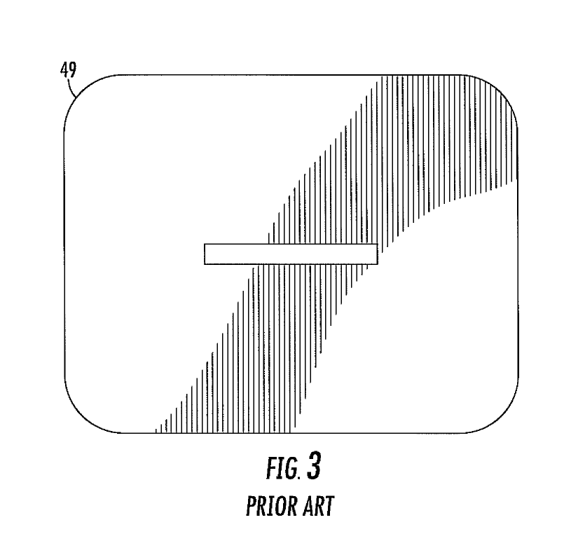

Referring additionally to FIG. 3, a conventional slot antenna 49 has evenly distributed current distribution on the horizontal slot parts. In contrast, the rigid mechanical stiffener 50 defining a slot antenna has asymmetric current distribution around slot 53 by having one relatively large current and the other relatively small current because of the different ground structure size. The advantage of this is that a symmetrical current distribution on the ground plane may not be needed. It should be noted that any opening along the ground plane can work as an antenna. In addition, efficiency increases because of the usage of the exposed metallic rigid mechanical stiffener 50, which implies that electromagnetic waves can directly propagate into the air without reduced loss of dielectric materials.

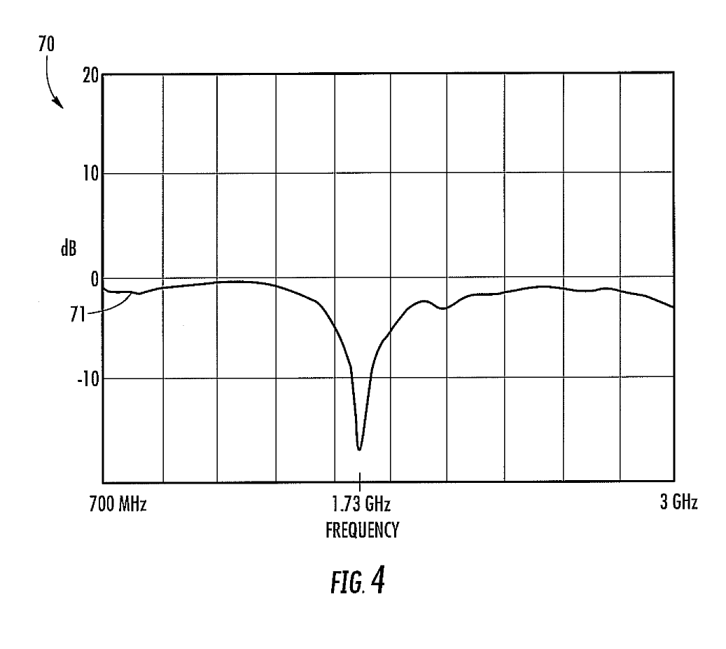

Referring now additionally to the graph 70 in FIG. 4, to verify the concept, a rigid mechanical stiffener 50 is connected from an antenna feed without having any other antenna traces. A semi-rigid cable was used to excite an RF signal to the antenna feed. A network analyzer (Agilent E5071C) was used to measure the reflection coefficient 71 of the slot antenna. The measured reflection coefficient 71 shows that the asymmetric-ground slot makes a relatively strong and wideband resonance at 1700 MHz. The magnitude of the reflection coefficient is −13 dB low, which corresponds to approximately 95% of power transmission.

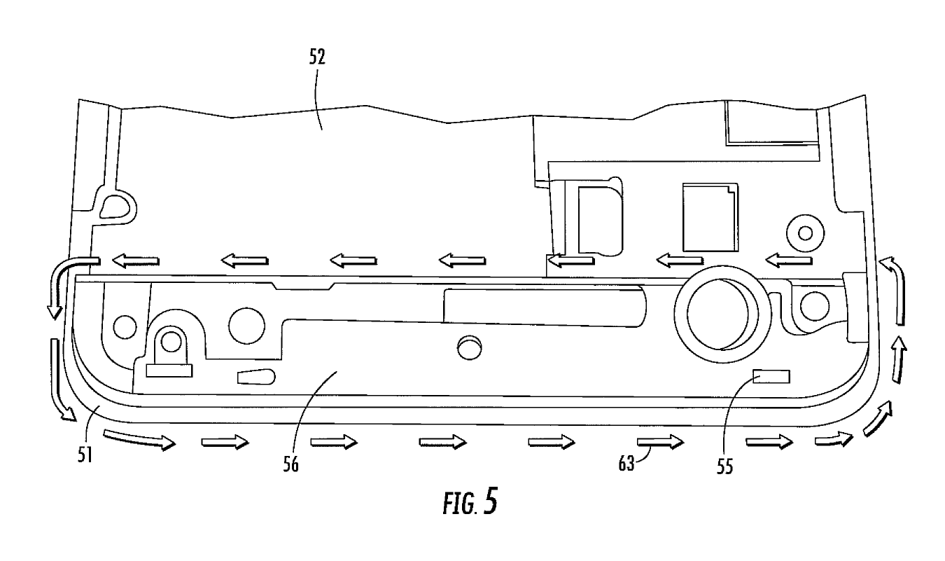

Referring now additionally to FIG. 5, a dielectric body 56 is positioned within the slot 53. The dielectric body 56 may be plastic, for example, and may provide increased strength. Additionally, the dielectric body 56 may contribute to the resonant frequency, for example, as does the geometry of the slot 53.

The current distribution 63 is also illustrated. The current distribution 63 flows along the perimeter of the slot 53 and the geometry of the slot determines the resonant frequency. A ground contact 55 is also shown on the rigid mechanical stiffener 50. The ground contact 55 may be a low resistive material, for example, to increase antenna performance.

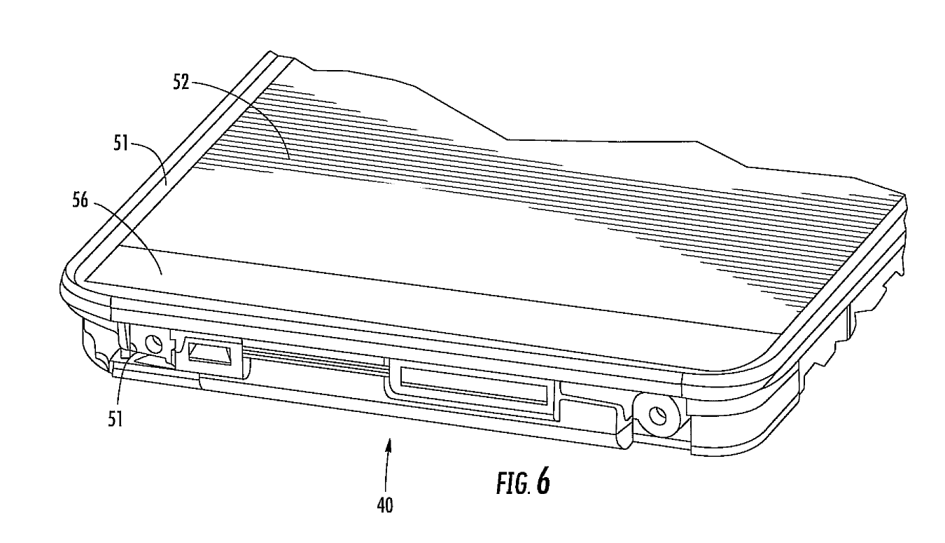

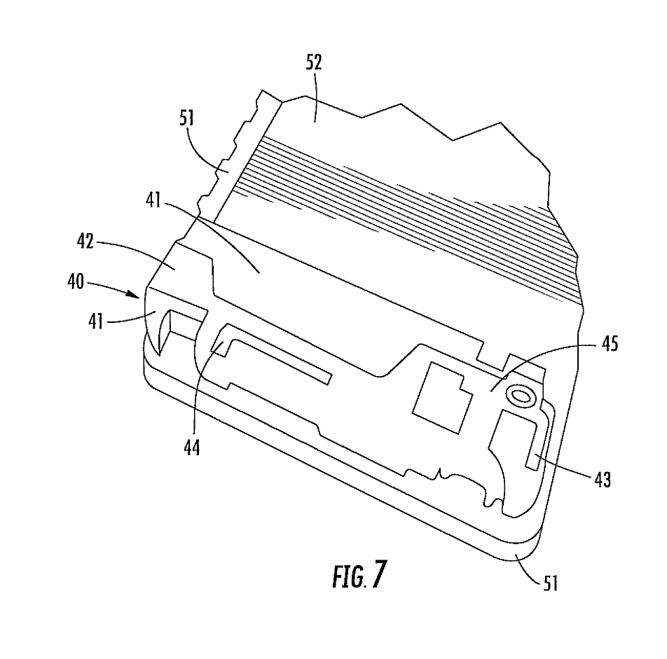

Referring now additionally to FIGS. 6 and 7, a relatively high-conductivity clip 57 or gasket may also be used for electrical contact. The clip 57 illustratively has a “L” shape. Furthermore, by pre-determining the mechanical structure of the rigid mechanical stiffener 50 for a specific wavelength, a relatively deep and wideband resonance may be achieved at a reduced amount of space and can significantly reduce antenna design time and cost. Additionally, the nature of the exposed slot antenna compared to other internal antennas can also provide higher antenna efficiency.

As noted above, the mobile wireless communications device 30 also includes a further antenna 40. The rigid mechanical stiffener 50 defining the slot antenna may be advantageously integrated with other antennas, for example the further antenna 40 for multiple-band operation to achieve multiple resonances. For example, the further antenna 40 may be for 3G wireless handheld applications and may be configured cooperate with the rigid mechanical stiffener 50 defining a slot antenna to operate at about 850 MHz, 900 MHz, 1700 MHz, 1800 MHz, 1900 MHz, and 2100 MHz.

The further antenna 40 in the form of an antenna assembly includes a substrate or antenna carrier 41. Two PIFAs 42, 43, which are flexible and carried by the substrate 41, and an open slot antenna 44 cover a band of interest. In some embodiments, the further antenna 40 or antenna assembly may be formed using laser direct structuring (LDS), or metal printing, etc., for example. It may be particularly desirable to evenly distribute the driven current to each antenna element, 42, 43, 44. Illustratively, a trident-shaped feed line 45 was designed in to address the current distribution To allocate the excited current substantially equally, the two PIFAs 42, 43 were branched from the direct grounding path to the rigid mechanical stiffener 50 to cover 850/900 MHz and the 2100 MHz. In this way, the relatively strong current flowing toward the rigid mechanical stiffener 50 is distributed to the side arms for other frequency band operation. By creating a narrow open slot 44 on the second PIFA 43, or “big trace” for 850/900 MHz, a resonance was also achieved at 1800/1900 MHz.

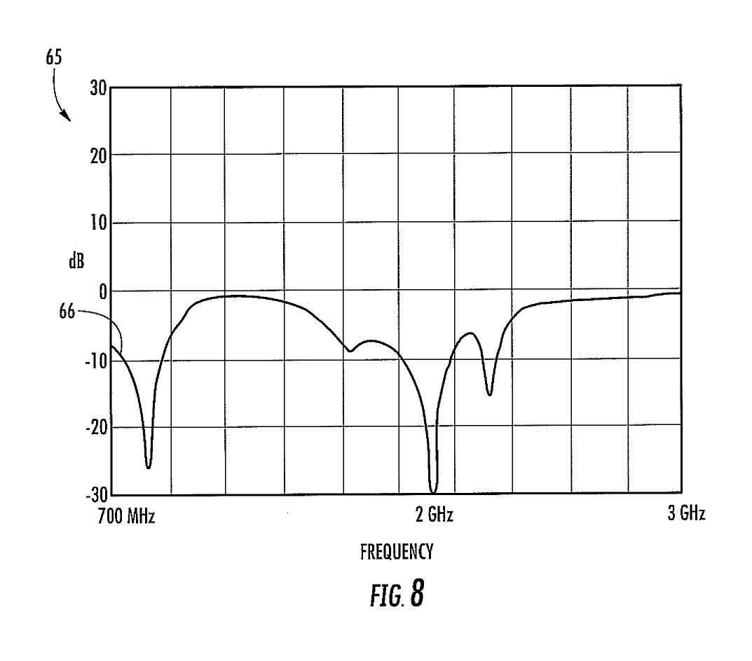

Referring now additionally to the graph 65 in FIG. 8, the measured reflection coefficient 66 for the mobile wireless communications device 30 with the further antenna 40 is illustrated. Illustratively, a relatively broad bandwidth was achieved with more than −7 dB of the reflection coefficient across the bandwidth of interest.

A method aspect is directed to a method of making a mobile wireless communications device that includes a portable housing 31, a printed circuit board 32 (PCB) carried the portable housing, and wireless transceiver circuitry 34 carried by the PCB. The method includes positioning the rigid mechanical stiffener 50 to be carried by a portable housing 31. The rigid mechanical stiffener 50 includes an electrically conductive material and has a slot 53 therein adjacent an end thereof to define a slot antenna. The method further includes coupling the wireless transceiver circuitry 34 to the slot antenna.

Example components of a mobile wireless communications device 1000 that may be used in accordance with the above-described embodiments are further described below with reference to FIG. 9. The device 1000 illustratively includes a housing 1200, a keyboard or keypad 1400 and an output device 1600. The output device shown is a display 1600, which may comprise a full graphic LCD. Other types of output devices may alternatively be utilized. A processing device 1800 is contained within the housing 1200 and is coupled between the keypad 1400 and the display 1600. The processing device 1800 controls the operation of the display 1600, as well as the overall operation of the mobile device 1000, in response to actuation of keys on the keypad 1400.

The housing 1200 may be elongated vertically, or may take on other sizes and shapes (including clamshell housing structures). The keypad may include a mode selection key, or other hardware or software for switching between text entry and telephony entry.

In addition to the processing device 1800, other parts of the mobile device 1000 are shown schematically in FIG. 9. These include a communications subsystem 1001; a short-range communications subsystem 1020; the keypad 1400 and the display 1600, along with other input/output devices 1060, 1080, 1100 and 1120; as well as memory devices 1160, 1180 and various other device subsystems 1201. The mobile device 1000 may comprise a two-way RF communications device having data and, optionally, voice communications capabilities. In addition, the mobile device 1000 may have the capability to communicate with other computer systems via the Internet.

Operating system software executed by the processing device 1800 is stored in a persistent store, such as the flash memory 1160, but may be stored in other types of memory devices, such as a read only memory (ROM) or similar storage element. In addition, system software, specific device applications, or parts thereof, may be temporarily loaded into a volatile store, such as the random access memory (RAM) 1180. Communications signals received by the mobile device may also be stored in the RAM 1180.

The processing device 1800, in addition to its operating system functions, enables execution of software applications 1300A-1300N on the device 1000. A predetermined set of applications that control basic device operations, such as data and voice communications 1300A and 1300B, may be installed on the device 1000 during manufacture. In addition, a personal information manager (PIM) application may be installed during manufacture. The PIM may be capable of organizing and managing data items, such as e-mail, calendar events, voice mails, appointments, and task items. The PIM application may also be capable of sending and receiving data items via a wireless network 1401. The PIM data items may be seamlessly integrated, synchronized and updated via the wireless network 1401 with corresponding data items stored or associated with a host computer system.

Communication functions, including data and voice communications, are performed through the communications subsystem 1001, and possibly through the short-range communications subsystem. The communications subsystem 1001 includes a receiver 1500, a transmitter 1520, and one or more antennas 1540 and 1560. In addition, the communications subsystem 1001 also includes a processing module, such as a digital signal processor (DSP) 1580, and local oscillators (LOs) 1601. The specific design and implementation of the communications subsystem 1001 is dependent upon the communications network in which the mobile device 1000 is intended to operate. For example, a mobile device 1000 may include a communications subsystem 1001 designed to operate with the Mobitex™, Data TAC™ or General Packet Radio Service (GPRS) mobile data communications networks, and also designed to operate with any of a variety of voice communications networks, such as AMPS, TDMA, CDMA, WCDMA, PCS, GSM, EDGE, etc. Other types of data and voice networks, both separate and integrated, may also be utilized with the mobile device 1000. The mobile device 1000 may also be compliant with other communications standards such as 3GSM, 3GPP, UMTS, 4G, etc.

Network access requirements vary depending upon the type of communication system. For example, in the Mobitex and DataTAC networks, mobile devices are registered on the network using a unique personal identification number or PIN associated with each device. In GPRS networks, however, network access is associated with a subscriber or user of a device. A GPRS device therefore typically involves use of a subscriber identity module, commonly referred to as a SIM card, in order to operate on a GPRS network.

When required network registration or activation procedures have been completed, the mobile device 1000 may send and receive communications signals over the communication network 1401. Signals received from the communications network 1401 by the antenna 1540 are routed to the receiver 1500, which provides for signal amplification, frequency down conversion, filtering, channel selection, etc., and may also provide analog to digital conversion. Analog-to-digital conversion of the received signal allows the DSP 1580 to perform more complex communications functions, such as demodulation and decoding. In a similar manner, signals to be transmitted to the network 1401 are processed (e.g. modulated and encoded) by the DSP 1580 and are then provided to the transmitter 1520 for digital to analog conversion, frequency up conversion, filtering, amplification and transmission to the communication network 1401 (or networks) via the antenna 1560.

In addition to processing communications signals, the DSP 1580 provides for control of the receiver 1500 and the transmitter 1520. For example, gains applied to communications signals in the receiver 1500 and transmitter 1520 may be adaptively controlled through automatic gain control algorithms implemented in the DSP 1580.

In a data communications mode, a received signal, such as a text message or web page download, is processed by the communications subsystem 1001 and is input to the processing device 1800. The received signal is then further processed by the processing device 1800 for an output to the display 1600, or alternatively to some other auxiliary I/O device 1060. A device may also be used to compose data items, such as e-mail messages, using the keypad 1400 and/or some other auxiliary I/O device 1060, such as a touchpad, a rocker switch, a thumb-wheel, or some other type of input device. The composed data items may then be transmitted over the communications network 1401 via the communications subsystem 1001.

In a voice communications mode, overall operation of the device is substantially similar to the data communications mode, except that received signals are output to a speaker 1100, and signals for transmission are generated by a microphone 1120. Alternative voice or audio I/O subsystems, such as a voice message recording subsystem, may also be implemented on the device 1000. In addition, the display 1600 may also be utilized in voice communications mode, for example to display the identity of a calling party, the duration of a voice call, or other voice call related information.

The short-range communications subsystem enables communication between the mobile device 1000 and other proximate systems or devices, which need not necessarily be similar devices. For example, the short-range communications subsystem may include an infrared device and associated circuits and components, a Bluetooth™ communications module to provide for communication with similarly-enabled systems and devices, or a near field communications (NFC) sensor for communicating with a NFC device or NFC tag via NFC communications.

Many modifications and other embodiments will come to the mind of one skilled in the art having the benefit of the teachings presented in the foregoing descriptions and the associated drawings. Therefore, it is understood that various modifications and embodiments are intended to be included within the scope of the appended claims.

That which is claimed is:

1. A mobile wireless communications device comprising:
a portable housing;
a printed circuit board carried by said portable housing;
a rigid mechanical stiffener carried by said portable housing and comprising an electrically conductive material, said rigid mechanical stiffener having a slot therein adjacent an end thereof to define a slot antenna; and
wireless transceiver circuitry carried by said PCB and coupled to the slot antenna.

2. The mobile wireless communications device of claim 1, wherein said rigid mechanical stiffener comprises:
a ring coupled to an inner periphery of said portable housing; and
a plate extending across said ring.

3. The mobile wireless communications device of claim 2, wherein said plate extends across a width of said portable housing.

4. The mobile wireless communications device of claim 1, further comprising a dielectric body within the slot.

5. The mobile wireless communications device of claim 1, wherein said rigid mechanical stiffener comprises metal.

6. The mobile wireless communications device of claim 1, further comprising a further antenna carried by said portable housing and coupled to said wireless transceiver circuitry.

7. The mobile wireless communications device of claim 6, wherein said further antenna comprises at least one planar inverted F-antenna (PIFA).

8. The mobile wireless communications device of claim 6, wherein said further antenna comprises a flexible antenna.

9. The mobile wireless communications device of claim 6, wherein said further antenna is carried between said portable housing and said rigid mechanical stiffener.

10. The mobile wireless communications device of claim 1, further comprising a display carried by said mechanical stiffener.

11. The mobile wireless communications device of claim 1, wherein said portable housing comprises a rear housing portion receiving said rigid mechanical stiffener therein.

12. A mobile wireless communications device comprising:
a portable housing;
a printed circuit board carried by said portable housing;
a rigid mechanical stiffener carried by said portable housing and comprising an electrically conductive material, said rigid mechanical stiffener having a slot therein adjacent an end thereof to define a slot antenna, and comprising
a ring coupled to an inner periphery of said portable housing, and
a plate extending across said ring;
wireless transceiver circuitry carried by said PCB and coupled to the slot antenna; and
a further antenna carried by said portable housing and coupled to said wireless transceiver circuitry.

13. The mobile wireless communications device of claim 12, wherein said plate extends across a width of said portable housing.

14. The mobile wireless communications device of claim 12, further comprising a dielectric body within the slot.

15. The mobile wireless communications device of claim 12, wherein said rigid mechanical stiffener comprises metal.

16. The mobile wireless communications device of claim 12, wherein said further antenna comprises at least one planar inverted F-antenna (PIFA).

17. The mobile wireless communications device of claim 12, wherein said further antenna comprises a flexible antenna.

18. The mobile wireless communications device of claim 12, wherein said further antenna is carried between said portable housing and said rigid mechanical stiffener.

19. A method of making a mobile wireless communications device comprising a portable housing, a printed circuit board (PCB) carried the portable housing, and wireless transceiver circuitry carried by the PCB, the method comprising:
positioning a rigid mechanical stiffener to be carried by a portable housing and comprising an electrically conductive material, the rigid mechanical stiffener having a slot therein adjacent an end thereof to define a slot antenna; and
coupling the wireless transceiver circuitry to the slot antenna.

20. The method of claim 19, wherein positioning the rigid mechanical stiffener comprises coupling a ring to an inner periphery of the portable housing; and wherein the rigid mechanical stiffener comprises a plate extending across the ring.

21. The method of claim 20, wherein the plate extends across a width of the portable housing.

22. The method of claim 19, further comprising positioning a dielectric body within the slot.

23. The method of claim 19, further comprising a coupling a further antenna to be carried by the portable housing to the wireless transceiver circuitry.
